(19) United States
(12) Patent Application Publication
(10) Pub. No.: US 2005/0045376 A1
(43) Pub. Date: Mar. 3, 2005

(54) High frequency multilayer circuit structure and method for the manufacture thereof

(75) Inventors: Young Chul Lee, Chungcheongbuk-do (KR); Chul Soon Park, Daejeon (KR); Yun Hee Cho, Daejeon (KR)

Correspondence Address: BACON & THOMAS, PLLC, 625 SLATERS LANE, FOURTH FLOOR, ALEXANDRIA, VA, 22314, US

(73) Assignee: Information And Communications University Educational Foundation, Seoul (KR)

(21) Appl. No.: 10/872,429

(22) Filed: Jun. 22, 2004

(30) Foreign Application Priority Data
Sep. 3, 2003 (KR) 10-2003-0061414

(51) Int. Cl. H05K 1/03; H05K 1/11; H05K 3/46

(52) U.S. Cl. 174/255; 156/89.11; 174/264; 29/846

(57) ABSTRACT

In a Conductor-Backed Coplanar Waveguide (CBCPW) structure, an effective dielectric constant of a parallel plate waveguide is higher than that of a Coplanar Waveguide (CPW), so that a parallel plate leakage is generated. To reduce the parallel plate leakage, the present invention provides air cavities, whose dielectric constant is low, in a multilayer circuit so that the effective dielectric constant of the parallel plate waveguide of the CBCPW structure can be lowered.

### FIELD OF THE INVENTION

The present invention relates to a multi-chip module; and, more particularly, to a multilayer circuit structure and a method for the manufacture thereof, which are suitable for reducing a parallel plate leakage in a high frequency band.

### BACKGROUND OF THE INVENTION

Multi-Chip Module (MCM) technologies are used for mounting and modularizing a plurality of semiconductor chips on a single board. The MCM technologies may be broadly classified into three types: a MCM-L (Laminated) technology using a multilayer Printed Circuit Board (PCB) technique, a MCM-D (Deposited) technology using a thin film technique, and a MCM-C (Co-fired) technology using a Low Temperature Co-fired Ceramic (LTCC) technique. The MCM-C technology, i.e., the technology of manufacturing a multi-chip module by using the LTCC technique, is applied mainly to a three-dimensional high frequency multilayer circuit that uses an LTCC substrate as a board.

A conventional high frequency multilayer circuit will be described hereinafter.

A Conductor-Backed Coplanar Waveguide (CBCPW) may be used as a transmission line by adopting an LTCC substrate as a board in a three-dimensional high frequency multilayer circuit. The CBCPW includes a Coplanar Waveguide (CPW) and a lower ground conductor and the CPW has upper ground conductors and a CPW signal line conductor. In the CBCPW, the upper ground conductors of the CPW and the lower ground conductor form a parallel plate waveguide structure. In the parallel plate waveguide structure, however, an effective dielectric constant is high, so that a loss of signal (LOS) is generated, wherein the LOS is referred to as a “parallel plate leakage.”

Accordingly, there has been used a technique of making the electric potential differences between the upper ground conductors and the lower ground conductor uniform by locating vias therebetween at regular intervals. However, the conventional technique has a problem described below.

The vias, the upper ground conductors and the lower ground conductor form a rectangular waveguide structure, so that a loss of signal is generated due to a resonance. Accordingly, to prevent the resonance attributable to the rectangular waveguide structure, the intervals between the vias should be set to be narrower than ½ of a wavelength of an operation signal. Referring to FIG. 1, the intervals between the vias refer not only to an interval W2 along a longitudinal direction but also to an interval W1 along a transversal direction. In case that the frequency of an operation signal is higher than, e.g., 60 GHz, the intervals W1 and W2 between the vias should be set to be narrower than 800 μm. However, a problem arises in that it is difficult to implement such a structure by using a multilayer LTCC process.

### SUMMARY OF THE INVENTION

It is, therefore, an object of the present invention to provide a high frequency multilayer circuit structure and a method for the manufacture thereof, in which air cavities are integrated in the multilayer circuit structure so that an effective dielectric constant of a parallel plate waveguide of a Conductor-Backed Coplanar Waveguide (CBCPW) structure can be lowered, thereby reducing a parallel plate leakage.

In accordance with one aspect of the present invention, there is provided a method for manufacturing a high frequency multilayer circuit structure by using a Low Temperature Co-fired Ceramic (LTCC), including the steps of: (a) forming vias and air cavities across a first layer green sheet; (b) forming vias across a second and a third layer green sheets; (c) inserting a conductive material into the vias of the first to third layer green sheets; (d) forming upper ground conductors and a signal line conductor on the third layer green sheet, and forming a lower ground conductor beneath the first layer green sheet; (e) laminating the first to third layer green sheets sequentially; and (f) firing the laminated green sheets.

In accordance with another aspect of the present invention, there is provided a high frequency multilayer circuit structure by using an LTCC, including: a lower layer green sheet across which vias and air cavities are formed; and an upper layer green sheet across which vias are formed, wherein the vias of the lower and upper layer green sheets are filled with a conductive material, an upper ground conductors and a signal line conductor are formed on the upper layer green sheet, and a lower ground conductor is formed beneath the lower layer green sheet.

### BRIEF DESCRIPTION OF THE DRAWINGS

The above and other objects and features of the present invention will become apparent from the following description of preferred embodiments given in conjunction with the accompanying drawings, in which:

FIG. 1 is a perspective view of a high frequency multilayer circuit structure in accordance with a preferred embodiment of the present invention;

FIG. 2 is a sectional view of the high frequency multilayer circuit structure; and

FIG. 3 is a flowchart showing a process of manufacturing the high frequency multilayer circuit structure.

### DETAILED DESCRIPTION OF THE PREFERRED EMBODIMENTS

Preferred embodiments of the present invention will now be described in detail with reference to the accompanying drawings.

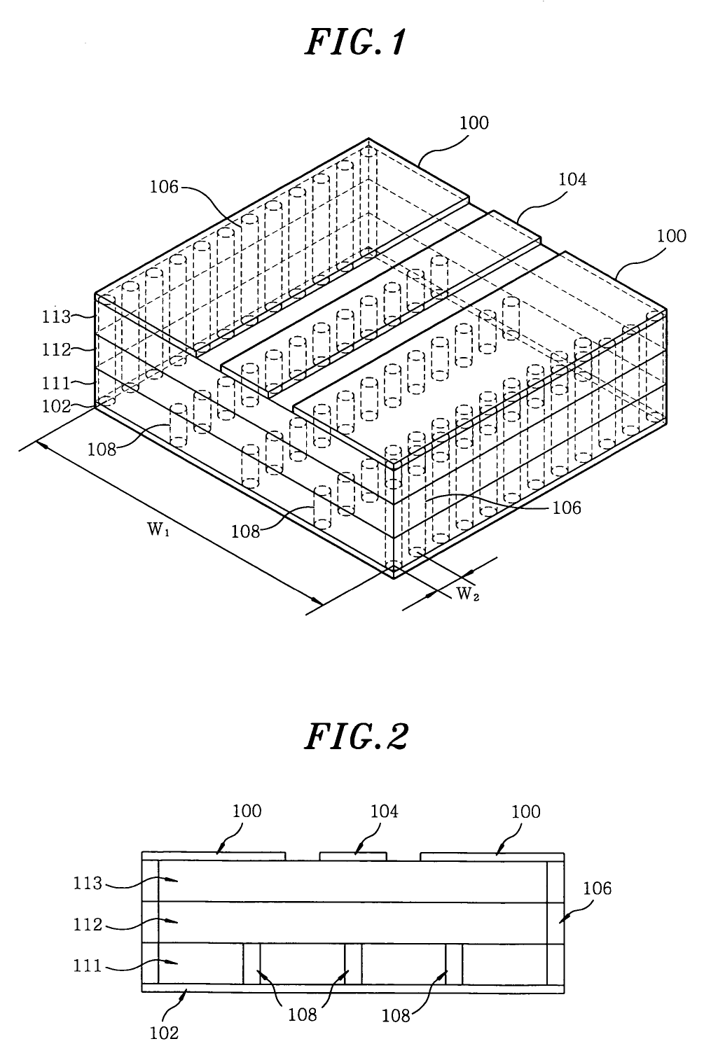

FIG. 1 is a perspective view of a high frequency multilayer circuit structure in accordance with a preferred embodiment of the present invention, and FIG. 2 is a sectional view of the high frequency multilayer circuit structure.

As shown in FIG. 2, the high frequency multilayer circuit structure includes upper ground conductors 100, a lower ground conductor 102, a Coplanar Waveguide (CPW) signal line conductor 104, vias 106 for connecting the upper and lower ground conductors 100 and 102, air cavities 108 and a first to a third layer green sheets 111 to 113.

The high frequency multilayer circuit structure is formed in such a way that the first to third layer green sheets 111 to 113 are laminated sequentially. Then, the lower ground conductor 102 is formed beneath the first layer green sheet 111, and the upper ground conductors 100 and the CPW signal line conductor 104 are formed on the third layer green sheet 113. Preferably, the CPW signal line conductor 104 is located between two upper ground conductors 100.

The vias 106 are formed across the first to third layer green sheets 111 to 113, and are filled with a conductive material. A diameter of each of the vias 106 is preferably about 100 to 200 μm.

The air cavities 108 implemented in accordance with the preferred embodiment of the present invention are formed across the first layer green sheet 111. In addition, the air cavities 108 can be formed across the second layer green sheet 112. A diameter of each of the air cavities 108 is preferably identical to that of the vias 106, and the air cavities 108 are filled with air in lieu of a conductive material. In this case, a dielectric constant of the air cavities 108 may be low.

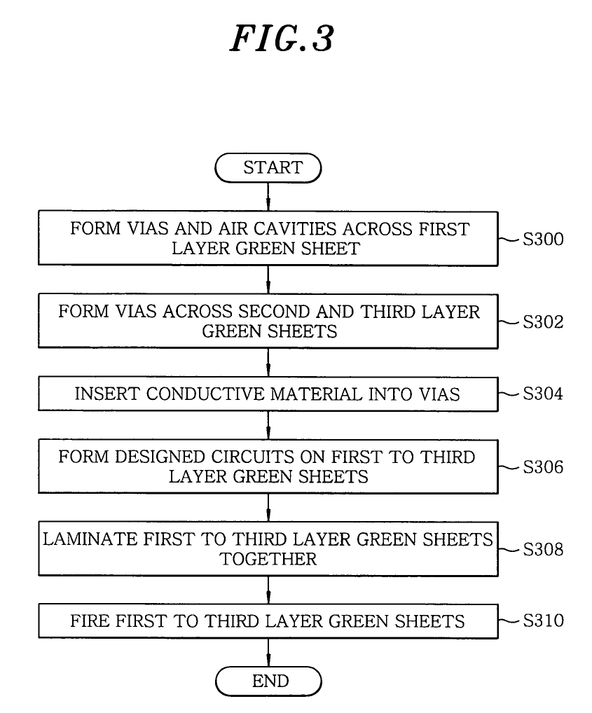

A process of manufacturing the high frequency multilayer circuit structure will be described in detail with reference to FIG. 3.

At step S300, the vias 106 and the air cavities 108 are formed across the first layer green sheet 111 by using, e.g., a punching method.

At step S302, the vias 106 are formed across the second and third layer green sheets 112 and 113 by using the same method as step S300.

At step S304, the vias 106 formed across the first to third layer green sheets 111 to 113 are filled with a conductive material, while the air cavities 108 formed across the first layer green sheet 111 are filled with air.

At step S306, designed circuits are formed on the first to third layer green sheets 111 to 113 by using, e.g., a printing method. In detail, the lower ground conductor 102 is formed beneath the first layer green sheet 111, and the upper ground conductors 100 and the CPW signal line conductor 104 are formed on the third layer green sheet 113. In this case, conductive pads for connecting the vias 106 of the first and second layer green sheets 111 and 112 and the vias 106 of the second and third layer green sheets 112 and 113 can be formed.

At step S308, the first to third green sheets 111 to 113, in which the designed circuits are formed, are laminated sequentially. Preferable lamination conditions are described below.

A lamination temperature is maintained at about 70° C., and lamination time is set to about 10 minutes. Further, a lamination pressure is set to about 2500 to 2700 psi that is lower than that of a general lamination process by about 10%. The reason why the lamination pressure of the preferred embodiment of the present invention is set to such a numerical range is to prevent the first to third green sheets 111 to 113 from being depressed and cracks from being generated around the air cavities 108 due to an excessive pressure.

At step S310, the laminated multilayer circuits are fired, and then entire process ends. Firing conditions are preferably set to a temperature of about 850° C. and time of about 15 minutes.

Although a multilayer circuit structure consisted of three layers has been described as an example, it is reasonable that the present invention can be applied to a multilayer circuit structure consisted of N layers, wherein N is a positive integer not less than 2. In this case, air cavities may be formed in a lower layer(s) among the N layers.

In accordance with the present invention, air cavities are integrated in a multilayer circuit structure, so that an effective dielectric constant of a parallel plate waveguide can be lowered. Accordingly, the present invention has an effect in that a parallel plate leakage can be reduced.

While the invention has been shown and described with respect to the preferred embodiments, it will be understood by those skilled in the art that various changes and modifications may be made without departing from the spirit and scope of the invention as defined in the following claims.

1. A method for manufacturing a high frequency multilayer circuit structure by using a Low Temperature Co-fired Ceramic (LTCC), comprising the steps of:
(a) forming vias and air cavities across a first layer green sheet;
(b) forming vias across a second and a third layer green sheets;
(c) inserting a conductive material into the vias of the first to third layer green sheets;
(d) forming upper ground conductors and a signal line conductor on the third layer green sheet, and forming a lower ground conductor beneath the first layer green sheet;
(e) laminating the first to third layer green sheets sequentially; and
(f) firing the laminated green sheets.

2. The method of claim 1, wherein each of the air cavities of the first layer green sheet has a diameter identical to that of the vias of the first to third layer green sheets.

3. The method of claim 2, wherein the diameter of the vias and the air cavities is about 100 to 200 μm.

4. The method of claim 1, wherein the step (e) is performed under a laminating condition which is set to lamination temperature of about 70° C., time of about 10 minutes, and pressure of about 2500 to 2700 psi.

5. The method of claim 1, wherein the step (f) is performed under a firing condition, which is set to firing temperature of about 850° C. and firing time of about 15 minutes.

6. The method of claim 1, wherein the step (d) further comprises the step of forming conductive pads for connecting the vias of the first to third layer green sheets.

7. A high frequency multilayer circuit structure by using an LTCC, comprising:
a lower layer green sheet across which vias and air cavities are formed; and
an upper layer green sheet across which vias are formed,
wherein the vias of the lower and upper layer green sheets are filled with a conductive material, upper ground conductors and a signal line conductor are formed on the upper layer green sheet, and a lower ground conductor is formed beneath the lower layer green sheet.

8. The high frequency multilayer circuit structure of claim 7, wherein each of the air cavities of the lower layer green sheet has a diameter identical to that of the vias of the lower and upper layer green sheets.

9. The high frequency multilayer circuit structure of claim 8, wherein the diameter of the vias and the air cavities is about 100 to 200 μm.
